(19) United States
(12) Patent Application Publication
(10) Pub. No.: US 2004/0080045 A1
(43) Pub. Date: Apr. 29, 2004

(54) Semiconductor device and chip-stack semiconductor device

(75) Inventors: Toshio Kimura, Kitakatsuragi-gun (JP); Yoshihisa Dotta, Nara-shi (JP)

Correspondence Address: NIXON & VANDERHYE, PC, 1100 N GLEBE ROAD, 8TH FLOOR, ARLINGTON, VA, 22201-4714, US

(73) Assignee: SHARP KABUSHIKI KAISHA, Osaka (JP)

(21) Appl. No.: 10/668,166

(22) Filed: Sep. 24, 2003

(30) Foreign Application Priority Data
Oct. 28, 2002 (JP) 2002-313530

(51) Int. Cl. H01L 23/48; H01L 23/52; H01L 29/40

(52) U.S. Cl. 257/736

(57) ABSTRACT

A semiconductor device has multiple through electrodes with the same cross-sectional area extending through a semiconductor chip linking its front to back surface. The number of electrodes used is determined in accordance with the magnitude of the electric current for the same signal. Hence, a semiconductor device and a chip-stack semiconductor device are provided which are readily capable of preventing the electrodes' resistance from developing excessive voltage drop, heat, delay, and loss, and also from varying from one electrode to the other.

### FIELD OF THE INVENTION

The present invention relates to semiconductor devices including a chip with through electrodes and also to chip-stack semiconductor devices incorporating such semiconductor chips vertically stacked on top of each other, for improved functionality, compactness, and reduced thickness.

### BACKGROUND OF THE INVENTION

CSP (Chip Size Package) semiconductor devices have been popularly used to meet the demand for compact electronics and automated manufacturing processes.

FIG. 15 shows the cross-sectional structure of a conventional CSP semiconductor device 100 as an example. The CSP semiconductor device 100 has gold wires 103 extending from electrode pads 102 formed along the periphery of a semiconductor chip 101. Through the gold wires 103, the semiconductor chip 101 is electrically connected to an interposer substrate, or circuit board, 104. The CSP semiconductor device 100 has also external lead electrodes 105 formed on the back of the interposer substrate 104, via which electrodes 105 the interposer substrate 104 is connected to an external device (not shown in the figure).

The wire bonding by means of the gold wires 103 electrically connects the electrode pads 102 on the semiconductor chip 101 to the interposer substrate 104. The gold wires 103 add an extra height to the device 100. They also need be sealed by molding resin 106 for protection. These factors present difficulties in reducing the thickness of the CSP semiconductor device 100.

FCB (Flip Chip Bonding) semiconductor devices like the one shown in FIG. 16(a) and those with through electrodes like the one shown in FIG. 16(b) offer solutions to these problems. These types of CSP semiconductor devices eliminate the need for wires, thereby allowing for thinner devices.

In the FCB semiconductor device 200 in FIG. 16(a), a semiconductor chip 201 is electrically connected to contact pads 205 on an interposer substrate 204 via protrusion electrodes 203 formed on electrode pads 202. The semiconductor chip 201 is positioned so that its surface 206 on which circuitry is formed is opposite to the interposer substrate 204. Sealing resin 207 resides between the surface 206 and the interposer substrate 204 to provide protection to the semiconductor chip 201 and the connecting parts.

In the semiconductor device 210 in FIG. 16(b) where electrical connections are provided by means of through electrodes, protrusion electrodes 215 electrically connect through electrodes 212 formed on a semiconductor chip 211 to contact pads 214 formed on an interposer substrate 213. Sealing resin 216 may be injected for sealing between the semiconductor chip 211 and the interposer substrate 213 if necessary; when this is the case, circuitry is formed on the upper surface 217 of the semiconductor chip 211.

Japanese Published Unexamined Patent Application 10-223833 (Tokukaihei 10-223833/1998; published on Aug. 21, 1998), Japanese Patent 3186941 (issued on May 11, 2001), U.S. Pat. No. 6,184,060 (Date of patent: Feb. 6, 2001), and other recent documents disclose proposed multi-chip semiconductor devices in which the foregoing semiconductor device includes film carrier semiconductor modules which are stacked vertically on top of each other and connected electrically for greater packaging efficiency.

Referring to FIG. 17, a multi-chip semiconductor device 300 described in Tokukaihei 10-223833/1998 includes three chips 301a, 301b, 301c stacked sequentially upwards from bottom. Each chip 301a, 301b, 301c is principally made up of a silicon substrate 302 carrying integrated devices; wiring layers 303 connecting the integrated devices in a predetermined pattern; through electrodes (connection plugs) 306 provided inside through holes 305 extending through the silicon substrate 302 and an interlayer insulating film 304 for the wiring layers 303 to electrically connect the chips 301a, 301b to the chips 301b, 301c; and an opening insulating film 307. The through electrodes 306 provide external connection terminals for grounding and power and various signal supplies, and are formed in accordance with uses for each chip 301a, 301b, 301c. The back of the silicon substrate 302, except for the openings for the through electrodes 306, is covered with a back insulating film 308.

Through the wiring layers 303 on the chip 301a, 301b, 301c are there provided electrode pads 309 electrically connected to the metal plugs 306. The through electrode 306 for the chip 301a is connected to the through electrode 306 for the chip 301b via an electrode pad 309 and a solder bump 310; meanwhile, the through electrode 306 for the chip 301b is connected to the through electrode 306 for the semiconductor device 301c via another electrode pad 309 and another solder bump 310.

Thus, the chips 301a, 301b, 301c are electrically connected with each other, offering a chip-stack semiconductor device.

In the conventional chip-stack semiconductor device, the terminal for the same signal is disposed at the same position on every chip, to provide electrical connections between the vertically stacked chips.

However, in the conventional chip-stack semiconductor device with through electrodes, all the through electrodes have equal cross-sectional areas of which the value is determined disregarding the functions of the through electrodes: e.g., the ground and power supply terminals have equal cross-sectional areas to those of the signal terminals despite the former conducting greater electric current than the latter. This raises problems that those terminals which need pass great electric current may heat up, delay signals, or develop other undesirable phenomena.

Further, in stacking chips with through electrodes, a chip adds an extra length to the through electrode connecting the top and the bottom chips. The extra length of the electrode translates into an extra resistance, resulting in voltage drop, heat, delay, and loss.

Further, the through electrodes vary greatly in interconnect line length, hence in resistance.

A solution to these problems may be given by enlarging the cross-sectional areas for the through electrodes passing large electric current. This is achieved by increased sizes of the openings for the through electrodes. However, providing through electrodes with differing opening sizes results in a variable etch rate, hence inconsistent etch depths. This means that in the polishing of the back of the semiconductor wafer, the metal material for the through electrodes, as well as the silicon (Si), must be polished. The process exerts excessive stress on the silicon, making it difficult to implement smooth back polishing.

### SUMMARY OF THE INVENTION

The present invention has an objective to offer a semiconductor device and a chip-stack semiconductor device which are capable of readily preventing the electrodes's resistance from developing excessive voltage drop, heat, delay, and loss, and also from varying from one electrode to the other.

In order to achieve the objective, a semiconductor device in accordance with the present invention includes a number of through electrodes with equal cross-sectional areas in a semiconductor chip linking a front surface to a back surface thereof, the number of the through electrodes being determined according to a magnitude of an electric current with respect to an identical signal.

According to the invention, the through electrodes have equal cross-sectional areas, and when required to conduct large electric current, the number of them determined in accordance with the magnitude of the electric current therethrough. This relatively increases the cross-sectional areas of the through electrodes, thereby reducing the resistance of the through electrodes and alleviating heating, signal delay, etc.

Meanwhile, through electrodes with differing opening sizes are provided to increase the cross-sectional areas of the through electrodes in accordance with the magnitude of the electric current, etch rate varies, and etch depths become inconsistent. This means that in the polishing of the back of the semiconductor wafer, the metal material for the through electrodes must also be polished. The process exerts excessive stress on the silicon (Si), making it difficult to implement smooth back polishing.

In the present embodiment, these problems do not occur, since the through electrodes have equal cross-sectional areas.

A semiconductor device can be thus offered which is capable of readily preventing the electrodes' resistance from developing excessive voltage drop, heat, delay, and loss, and also from varying from one electrode to the other.

A chip-stack semiconductor device in accordance with the present invention includes a plurality of such semiconductor chips being stacked.

According to the invention, the above-described semiconductor chips are stacked on top of each other. The number, hence the combined cross-sectional area, of the through electrodes required to make interconnects over an extended length can be increased in accordance with that length. This reduces the resistance of the electrodes and alleviates voltage drop, heat, delay, and loss. Variations in resistance between terminals can also be reduced.

In addition, designating some of the through electrodes as non-contact through electrodes not electrically connected to the semiconductor chips allows a current to flow all the way from the top chip to the bottom chip.

Therefore, a chip-stack semiconductor device can be offered which is capable of readily preventing the electrodes' resistance from developing excessive voltage drop, heat, delay, and loss, and also from varying from one electrode to the other.

Additional objects, advantages and novel features of the invention will be set forth in part in the description which follows, and in part will become apparent to those skilled in the art upon examination of the following or may be learned by practice of the invention.

### BRIEF DESCRIPTION OF THE DRAWINGS

FIG. 1(a) is a plan view illustrating an embodiment of a semiconductor device according to the present invention, and FIG. 1(b) is a cross-sectional view of the semiconductor device along line A-A.

FIG. 2 is a cross-sectional view illustrating a semiconductor device mounted on an interposer substrate.

FIG. 3 is a cross-sectional view illustrating a semiconductor device with both a contact through electrode and a non-contact through electrode.

FIGS. 4(a)-4(d) are cross-sectional views illustrating manufacturing steps for the through electrodes in the semiconductor device.

FIGS. 5(a)-5(d) are cross-sectional views illustrating manufacturing steps for the through electrodes in the semiconductor device, subsequent to the step in FIG. 4(d).

FIGS. 6(a)-6(c) are cross-sectional views illustrating manufacturing steps for the through electrodes in the semiconductor device, subsequent to the step in FIG. 5(d).

FIGS. 7(a)-7(c) are cross-sectional views illustrating manufacturing steps for the through electrodes in the semiconductor device, subsequent to the step in FIG. 6(c).

FIGS. 8(a)-8(d) are cross-sectional views illustrating manufacturing steps for the through electrodes in the semiconductor device, subsequent to the step in FIG. 7(c).

FIG. 9 is a cross-sectional view illustrating a semiconductor device with gold bumps being formed on the through electrodes.

FIG. 10 is a cross-sectional view illustrating an embodiment of a chip-stack semiconductor device in accordance with the present invention.

FIG. 11 is a cross-sectional view illustrating the chip-stack semiconductor device where the upper and lower chips include through electrodes located at different positions, but electrically connected.

FIGS. 12(a)- 12(d) are cross-sectional views illustrating manufacturing steps for the chip-stack semiconductor device in FIG. 11.

FIGS. 13(a)-13(c) are cross-sectional views illustrating manufacturing steps, subsequent to the step in FIG. 12(d).

FIG. 14 is a cross-sectional view illustrating another embodiment of a chip-stack semiconductor device in accordance with the present invention.

FIG. 15 is a cross-sectional view illustrating a conventional semiconductor device.

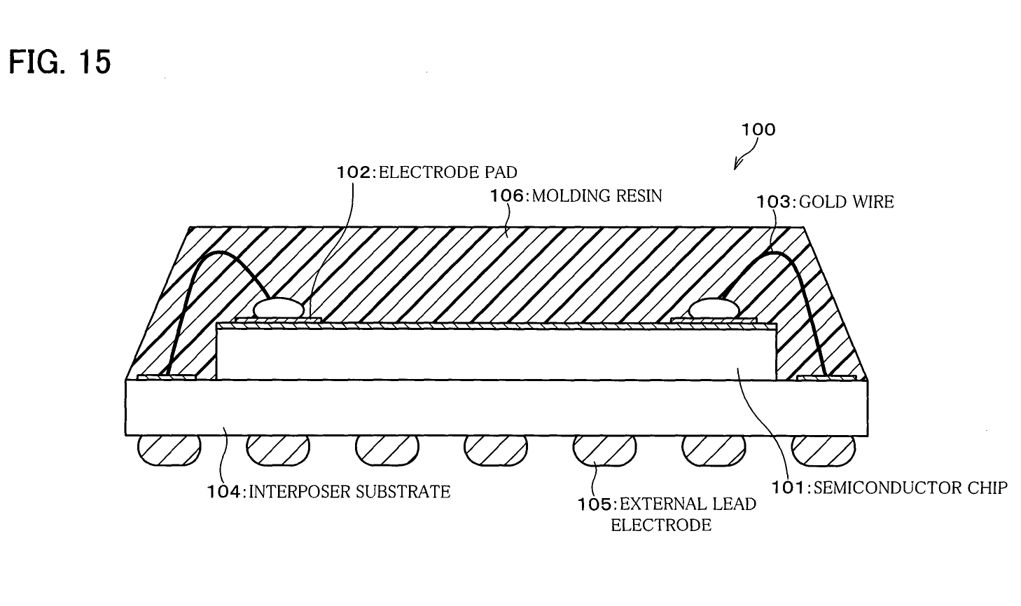

FIGS. 16(a), 16(b) are cross-sectional views illustrating another conventional semiconductor device.

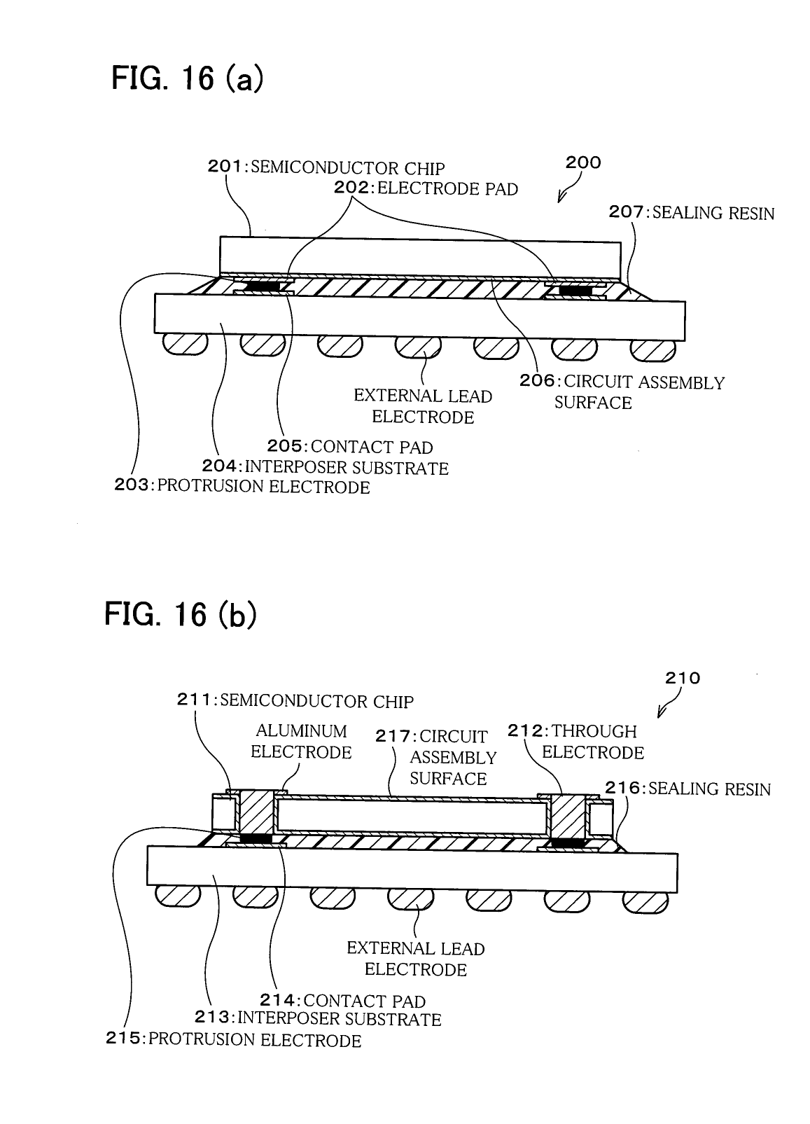

FIG. 17 is a cross-sectional view illustrating a conventional chip-stack semiconductor device.

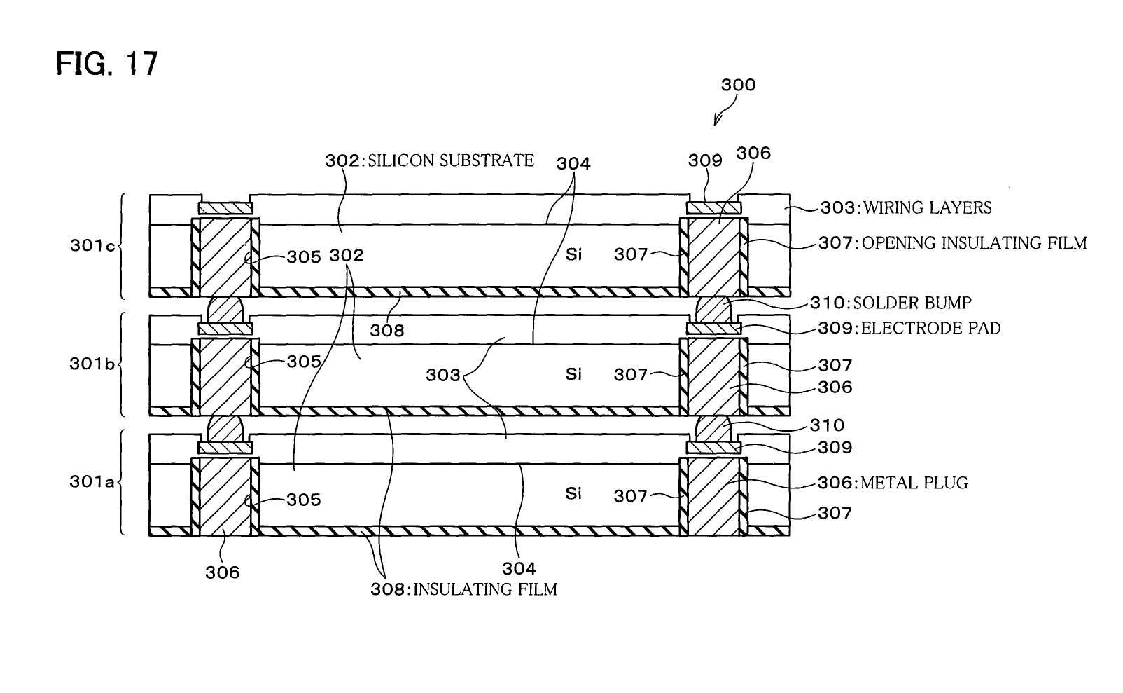

### DESCRIPTION OF THE EMBODIMENTS

### Embodiment 1

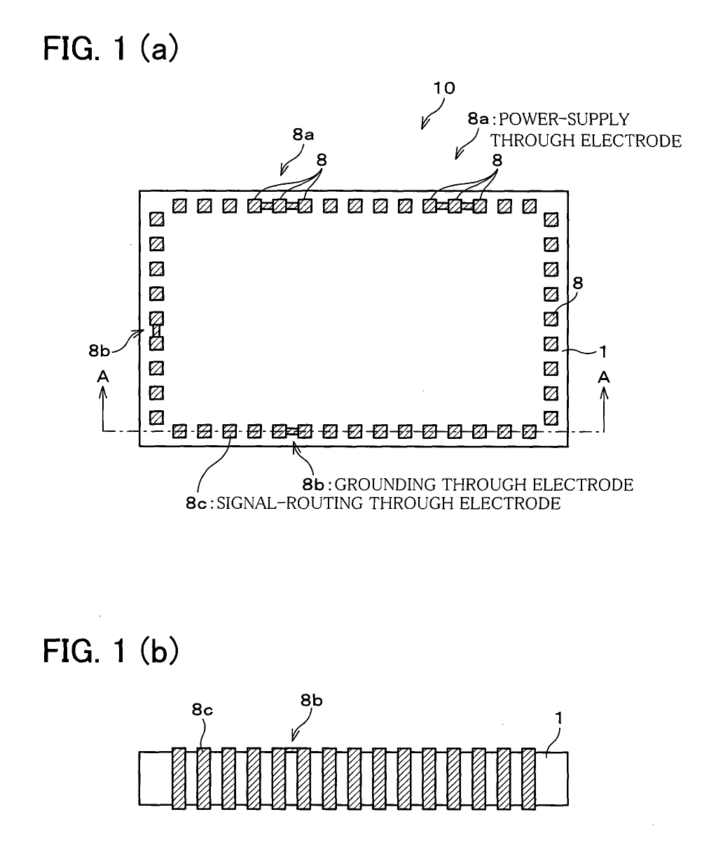

Referring to FIG. 1 through FIG. 9, the following will describe an embodiment according to the present invention.

FIG. 1(a) is a plan view illustrating a semiconductor device 10 in the present embodiment. A semiconductor chip 1 in the semiconductor device 10 has along its periphery multiple through electrodes 8 made through the semiconductor chip 1.

As shown in FIGS. 1(a), 1(b), in the present embodiment, the through electrodes 8 have equal cross-sectional areas, and a number of them is used together as determined in accordance with the value of the electric current passing through them.

The through electrodes 8 in the semiconductor device 10 are divided into three major types: power-supply through electrodes 8a, grounding through electrodes 8b, and signal-routing through electrodes 8c. The power-supply through electrode 8a, the grounding through electrode 8b, and the signal-routing through electrode 8c are made up of different numbers of through electrodes 8. Specifically, the power-supply through electrode 8a is made of three through electrodes 8. The grounding through electrode 8b is made up of two through electrodes 8. The signal-routing through electrode 8c is made up of one through electrode 8. Both the power-supply through electrode 8a and the grounding through electrode 8b are made up of a greater number of through electrodes 8 than the signal-routing through electrode 8c.

Reasons follow: the power-supply through electrode 8a and the grounding through electrode 8b conduct current of a greater value than does the signal-routing through electrode 8c; therefore, the power-supply through electrode 8a and the grounding through electrode 8b conducting current of a greater value are made up of a greater number of through electrodes 8, hence a greater cross-sectional area, than the signal-routing through electrode 8c conducting electric current of a smaller value. In the above example, the power-supply through electrode 8a, the grounding through electrode 8b, and the signal-routing through electrode 8c are made up of three, two, and one through electrode(s) 8 respectively.

Alternatively, the power-supply through electrode 8a, the grounding through electrode 8b, and the signal-routing through electrode 8c may be made up of a number of through electrodes 8 (i.e., a cross-sectional area) which increases with an increase in the electric current passing through them. Further, in the example, the through electrode 8 is presumed to be rectangle. Alternatively, it may be circular or take another shape.

Increasing the number of through electrodes 8 for the terminal required to conduct large electric current, and hence the area of the combined electrode, as discussed in the foregoing lowers the resistance of the power-supply through electrode 8a and the grounding through electrode 8b and alleviates heating, signal delay, etc.

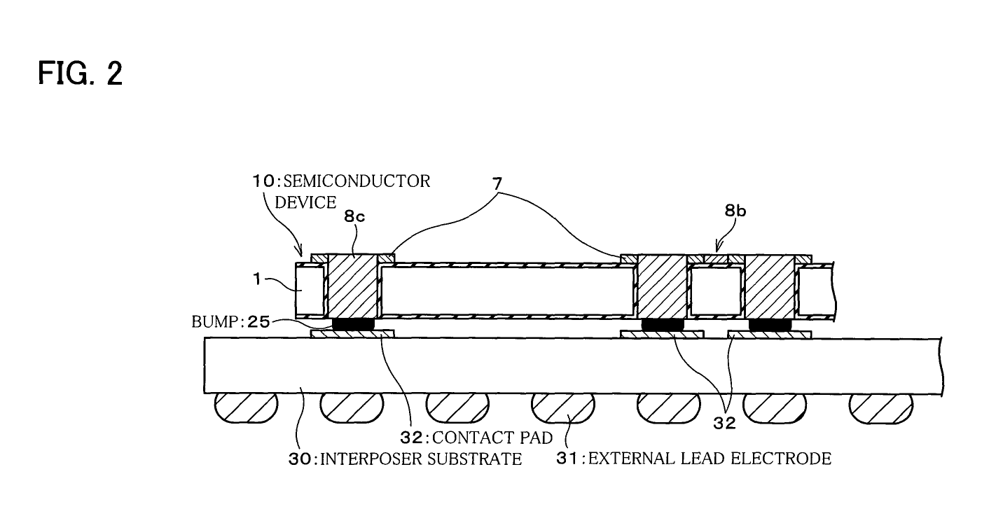

In the semiconductor device 10, as shown in FIG. 2, an interconnect pattern extends from a device region (not shown in the figure) on the semiconductor chip 1 and connects to the through electrodes 8 at electrode pads 7. More specifically, in the semiconductor chip 1, numerous fine lines (not shown in the figure) extend from the device region as an interconnect pattern. The electrode pad 7 refers to the relatively large electrode terminal disposed on the tip of an interconnect pattern along the periphery of the semiconductor chip 1 to provide an external electrical input/output to the interconnect pattern. Conventionally, wire bonds are provided on the electrode pads 7.

The through electrode 8 is electrically connected to an external lead electrode 31 on the back of the interposer substrate 30. More specifically, external lead electrodes 31 are formed on the back of the interposer substrate 30. The external lead electrodes 31 are electrically connected to contact pads 32 on the front surface in via holes (not shown in the figure) made through the interposer substrate 30. The contact pads 32 are provided at the same surface positions as the through electrodes 8 in the semiconductor device 10. Connecting the contact pads 32 to the through electrodes 8 (the power-supply through electrodes 8a, the signal-routing through electrodes 8c, etc.) with intervening bumps 25 establishes electrical connections between the through electrodes 8 in the semiconductor device 10 and the bare contact pads 32 on the back of the interposer substrate 30. Thus, the device region on the semiconductor chip 1 is electrically connected to the external lead electrodes 31 which can be further connected to, for example, a power supply for a printed circuit board (not shown in the figure).

It is presumed in the above description that the through electrode 8 in the semiconductor device 10 is connected to the interposer substrate 30 beneath it via the bump 25; alternatively, for example, wires may be connected to the front surface of the through electrodes 8.

In the present embodiment, the interposer substrate 30 is used as a relay between the semiconductor device 10 and a circuit board (not shown in the figure). The pitch of the electrode pads 7 on the semiconductor device 10 is small, and does not match that of the electrodes on a circuit board or a mother board. The interposer substrate 30 acts to convert the pitch. In addition to the pitch conversion for the electrode pads 7 on the semiconductor device 10, the interposer substrate 30 plays another role in, for example, alleviating stress between the semiconductor device 10 and the circuit board (not shown in the figure).

Reducing the chip size of the semiconductor device 10 to a minimum is an important cost-cutting factor; therefore, normally, the through electrodes 8 are preferably as small as possible.

In the present embodiment, the signal-routing through electrode 8c measures 10 μm on each side, and the semiconductor device 10 is made as thin as 50 μm, to achieve compactness and slimness. The original semiconductor wafer 11 (detailed later) is about 600-700 μm in thickness. It is polished down generally to a thickness of about 300-400 μm and for some recent CSP (chip size package) and other applications, to a thickness of about 150-200 μm.

However, the power supply terminal and the ground terminal must conduct relatively large electric current when compared to the signal terminal. It is therefore preferred if the former have as low line resistance as possible; otherwise, they may cause excessive voltage drop, heat, signal delay, etc. Consequently, it is preferred if either the power-supply through electrode 8a or the grounding through electrode 8b, connected respectively to the power supply terminal and the ground terminal, has an increased cross-sectional area of twice to five times that of the signal-routing through electrode 8c connected to the signal terminal.

In the present embodiment, to lower the resistance of the power supply and ground terminals, the power-supply through electrode 8a and the grounding through electrode 8b, connected respectively to the power supply terminal and the ground terminal, are designed to made up of two or three through electrodes 8, which amounts to a cross-sectional area greater than the cross-sectional area of the signal terminal.

The design lowers the line resistance of the power supply and ground terminals conducting large electric current, hence alleviating heating and signal delay.

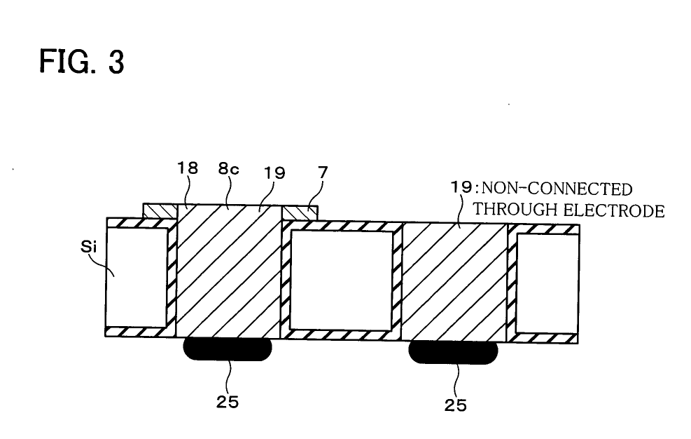

The foregoing description presumes that the through electrodes 8 are all connected to the electrode pads 7 on the semiconductor chip 1; an alternative example is shown in FIG. 3 where some of the through electrodes 8 are connected to the electrode pads 7 on the semiconductor chip 1 and redesignated as contact through electrodes 18, and the rest is not connected to the electrode pads 7 and redesignated as non-contact through electrodes 19.

The formation of the non-contact through electrodes 19 in the semiconductor device 10 as in the foregoing is advantageous in that the non-contact through electrodes 19 provides heat generated in the semiconductor device 10 exit paths to the interposer substrate 30 or another substrate. Other uses of the non-contact through electrodes 19 will be detailed later in embodiments 2, 3.

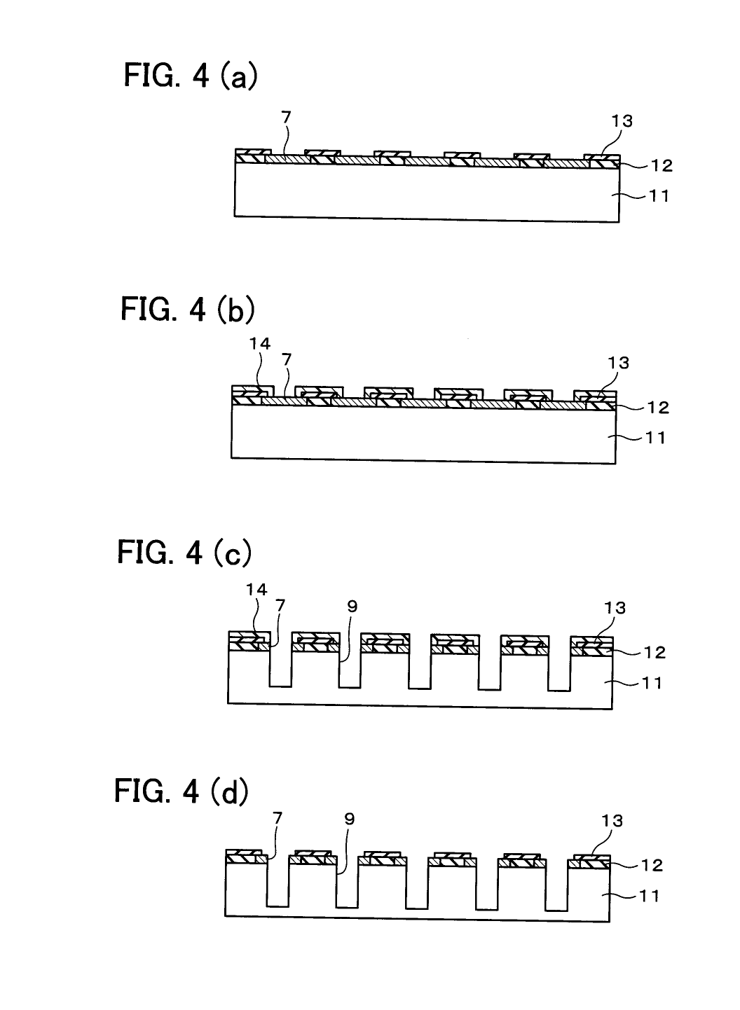

Now, referring to FIG. 4 through FIG. 9, a manufacturing method will be described for the semiconductor device 10 with the contact through electrodes 18 and the non-contact through electrodes 19. The description will mainly focus on the formation method of the through electrodes 8.

First, refer to FIG. 4(a) showing the cross-sectional structure of the silicon (Si) semiconductor wafer 11 near the electrode pads 7.

In FIG. 4(a), a silicon dioxide (SiO₂) thermal oxide film 12 and aluminum-silicon (Al—Si) or aluminum-copper (Al—Cu) electrode pads 7 are formed on the surface of the silicon (Si) semiconductor wafer 11. Further, the surface of the thermal oxide film 12 and some of the electrode pads 7 are protected with a P-SiN insulating film 13. The surface insulating film 13 is, for example, 0.7 μm thick on the electrode pads 7. The P-SiN insulating film 13 is a compound of silicon (Si) nitrogen (N), and “P” stands for “plasma.” The P-SiN insulating film 13 has a dielectric constant of 7, greater than a silicon oxide film (oxide film=4), and is therefore used as a passivation film. The P-SiN insulating film 13 is usually grown in a furnace; after the electrode pads 7 are patterned, however, the film 13 cannot be processed at high temperatures due to melting point constraints. Accordingly, the film 13 is grown by plasma discharge in the present embodiment, because the resulting film 13 will have a poorer quality due to lower process temperature than a film grown in a furnace, but exhibit a superior dielectric constant and other properties to an oxide film.

Moving on to FIG. 4(b), grooves 9 are formed in preparation for the formation of the through electrodes 8 as follows. After resist is uniformly applied, openings for the grooves 9 are made in the electrode pads 7 using a reduction projection aligner to expose the electrode pads 7 to light.

Next, as shown in FIG. 4(c), the lower aluminum-silicon (Al—Si) or aluminum-copper (Al—Cu) electrode pads 7 are dry etched, immediately followed by polymer removal and water washing to prevent erosion to occur. Subsequently, the thermal oxide film 12 is dry etched. To facilitate successive etching of different film materials and achieve a minimum level of exposure to air, the process is preferably implemented using a multi-chamber dry etcher; otherwise, a single chamber must be used to accommodate an atmosphere of different gases, and especially, metal will erode due to excessive exposure to air.

As the etch step reaches the silicon (Si) substrate of the semiconductor wafer 11, the silicon (Si) substrate is etched up to 50 μm to 70 μm using another dry etcher for deep etching.

Then, as shown in FIG. 4(d), after the etching is completed, the polymer and resist are removed.

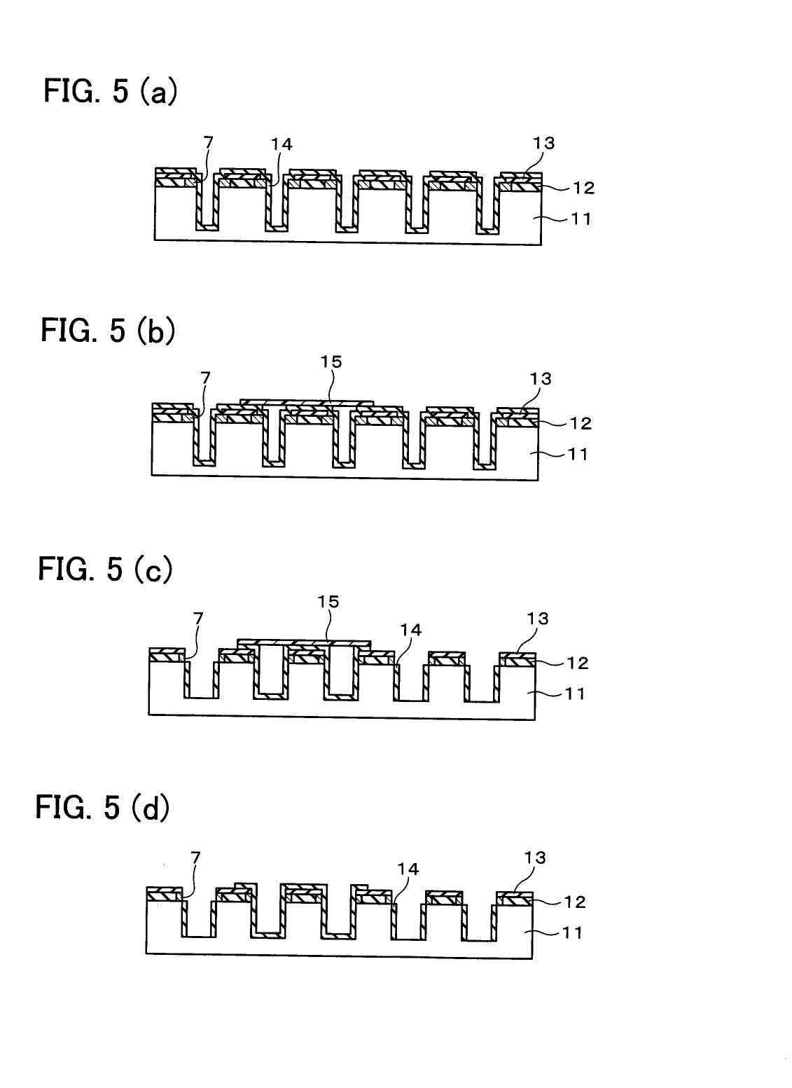

Now, moving on the FIG. 5(a), a side wall insulating film 14 is grown using an insulating film growing facility. The side wall insulating film 14 grows also on the wafer surface. This is removed by etch-back using a dry etcher. The side wall insulating film 14 should be retained in the grooves 9 for the non-contact through electrodes 19. As shown in FIG. 5(b), a resist film 15 is attached, patterned using a reduction projection aligner, and covered. Thereafter, as shown in FIG. 5(c), the side wall insulating film 14 is etched away from the surface.

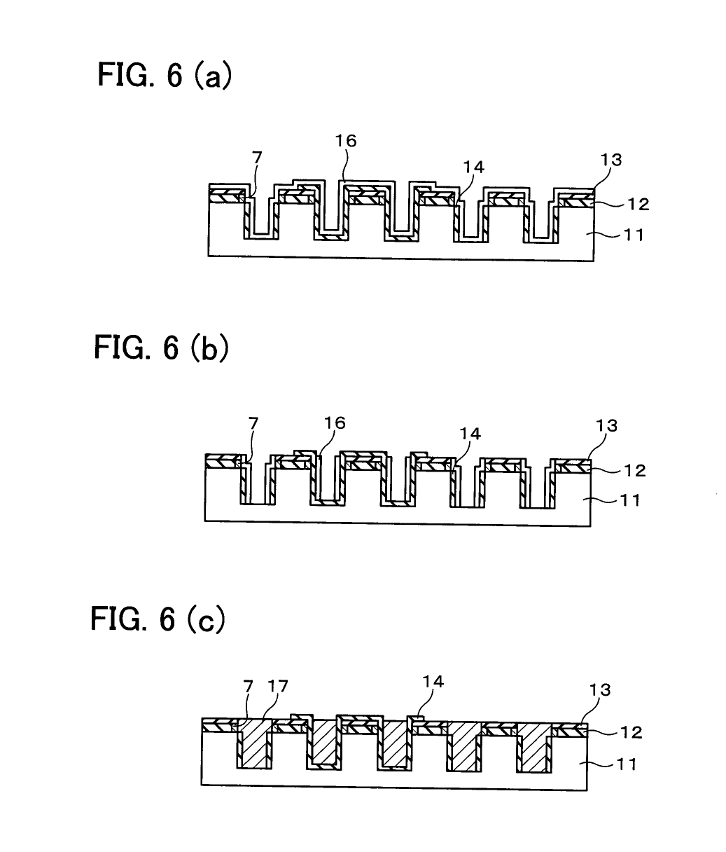

Subsequently, the resist film 15 is peeled as shown in FIG. 5(d), a barrier metal 16 is sputtered as shown in FIG. 6(a) and etched away except from inside the grooves 9 and top parts of the wafer where a pattern needs to be rewired as shown in FIG. 6(b). Further, as shown in FIG. 6(c), a conductor 17 is grown by an electroless plating technique.

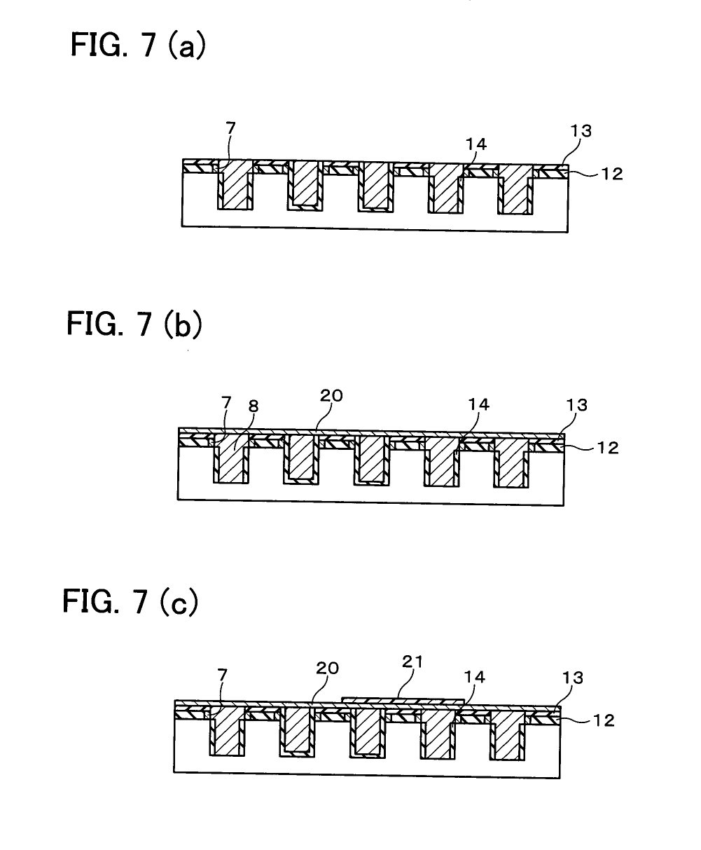

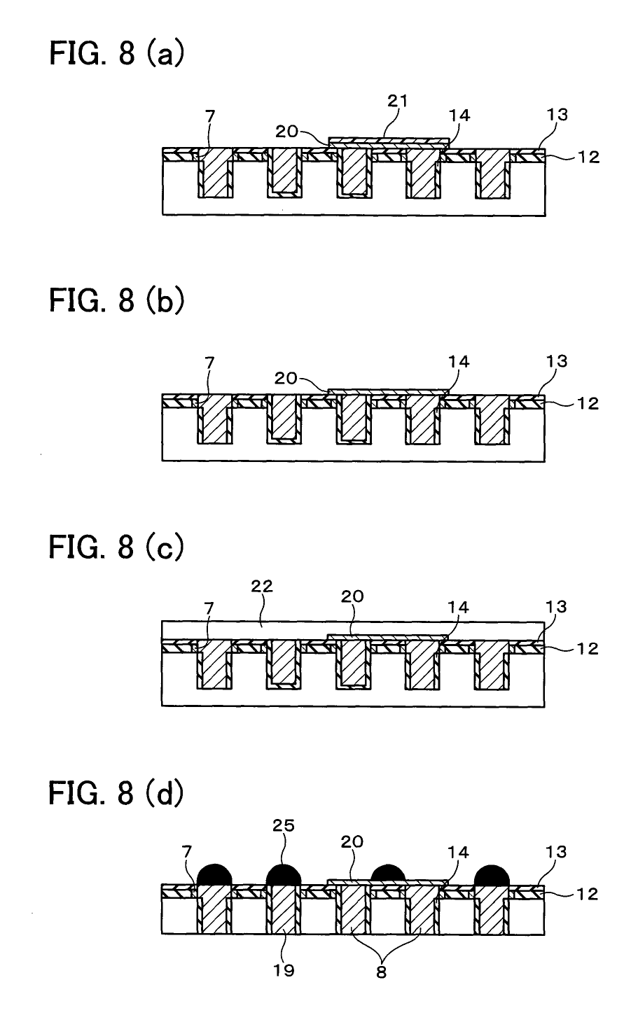

Subsequently, as shown in FIG. 7(a), residues of the insulating film 13 are removed from the wafer surface by CMP (chemical mechanical polishing). Thereafter, a conductive film 20 is sputtered as shown in FIG. 7(b), a resist 21 is applied as shown in FIG. 7(c) and etched as shown in FIG. 8(a) to short the through electrodes 8 at places where resistance is high or interconnection is long, achieving reduced resistance.

CMP is a method of polishing where a wafer attached to a spindle is pressed to a polish pad on the surface of a rotation table while pouring a polishing solution (slurry) containing silica particles onto the wafer surface. CMP exploits both a chemical mechanism of oxidizing with a slurry the surface of a material layer to be polished and a mechanical mechanism of mechanical carving the oxidized layer. Applicable in two fields (insulating films and metals), CMP is a technology which can completely planarize the wafer surface in IC manufacture. Insulating film CMP is used to planarize an interlayer insulating film, embed an STI, and form an insulating film. Metal CMP is used to form tungsten plugs and in a copper damascene step.

Subsequently, the resist 21 is peeled as shown in FIG. 8(b), and a support board 22 is attached to the wafer surface using a UV adhesive sheet, and the back of the semiconductor wafer 11 is polished, as shown in FIG. 8(c).

The through electrodes 8 are exposed on the back of the wafer as a result of the polishing, and the support board 22 is removed, as shown in FIG. 8(d). Subsequently, the bumps 25 are formed on the grown conductive film 20 and the rewired shortings, which completes the manufacture.

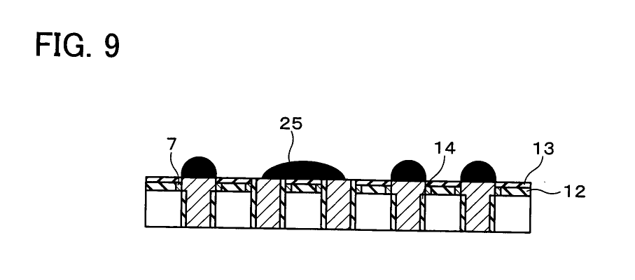

In the example, the conductive film 20 is used to connect a through electrode 8 to another. Alternatively, for example, as shown in FIG. 9, the bumps 25 may be formed from gold wire bumps. In this case, the bumps 25 need be surrounded by a conductor.

As discussed in the foregoing, in the semiconductor device 10 in the present embodiment, the through electrodes 8 have equal cross-sectional areas, and when required to conduct large electric current, a number of through electrodes 8 are used together in accordance with the magnitude of the electric current. Thus, the cross-sectional area of each through electrode 8 is added up. This provides a relatively large combined cross-sectional area and reduced resistance, alleviating heating, signal delay, etc.

On the other hand, if the opening areas of the grooves 9 for the through electrodes 8 are varied in size to increase the cross-sectional areas of the through electrodes 8 in accordance with the magnitude of electric current, etch rate varies, and resultant etch depths are inconsistent. This means that in the polishing of the back of the semiconductor wafer 11, the metal material for the through electrodes 8, as well as the silicon, must be polished. The process exerts excessive stress on the silicon (Si), making it difficult to implement smooth back polishing.

In the present embodiment, these problems do not occur, since the through electrodes 8 have equal cross-sectional areas.

A semiconductor device 10 can be thus offered which is capable of readily preventing the electrodes' resistance from developing excessive voltage drop, heat, delay, and loss, and also from varying from one electrode to the other.

In addition, in the semiconductor device 10 in the present embodiment, at least one type of the through electrodes 8 is the contact through electrodes 18 which are electrically connected to the device region via the electrode pads 7 on the semiconductor chip 1.

Therefore, the contact through electrode 18, electrically connected to the semiconductor chip 1, for a terminal required to conduct large electric current is made up of an increased number of through electrodes 8 so as to produce a relatively increased, combined cross-sectional area. The structure enables efficient operation of the semiconductor chip 1.

In addition, in the semiconductor device 10 in the present embodiment, at least one type of the through electrodes 8 is the non-contact through electrodes 19 which are not connected to the electrode pads 7 on the semiconductor chip. Therefore, the heat generated in the semiconductor device 10 can be discharged outside via the non-contact through electrodes 19.

The ground and power supply terminals must conduct larges electric current than the signal terminal.

To deal with this issue, in the present embodiment, the power-supply through electrodes 8 connected to either the ground terminal or the power supply terminal of the semiconductor chip 1 are made up of a larger number of through electrodes 8 than the signal-routing through electrode 8c connected to the signal terminal.

Therefore, increasing the number of constituting through electrodes 8 for, hence the cross-sectional area of, the power-supply through electrode 8a either for the ground terminal or the power supply terminal of the semiconductor chip 1 required to conduct large electric current, reduces the resistance of that power-supply through electrode 8a, alleviating heat, signal delay, etc. Variations in resistance between terminals can also be reduced.

### Embodiment 2

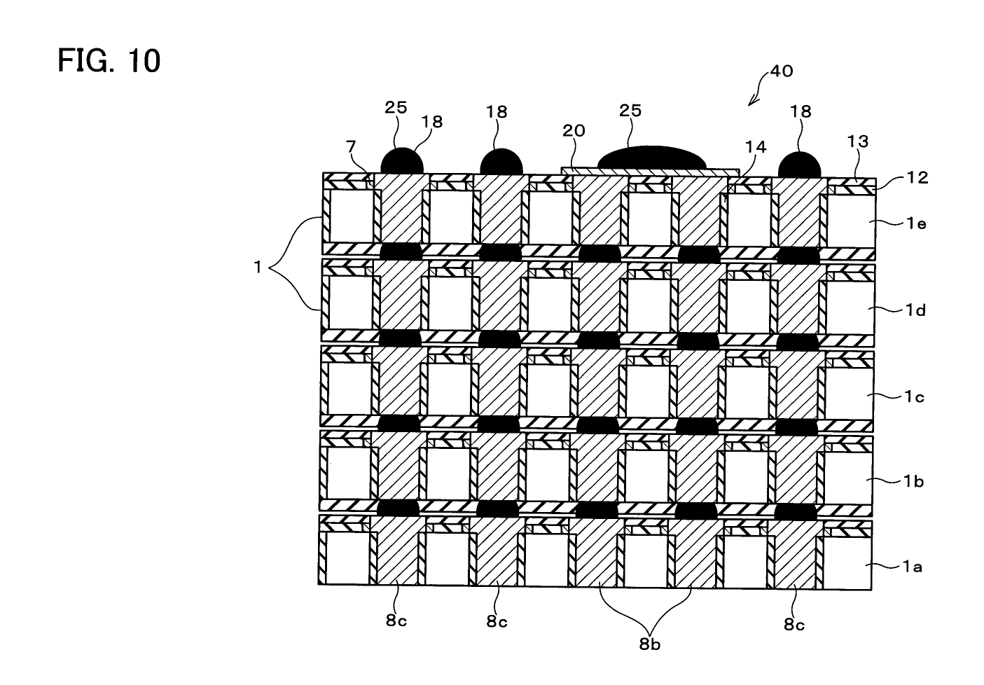

The following will describe another embodiment of the present invention with reference to FIG. 10 through FIG. 13. For convenience, members of the present embodiment that have the same arrangement and function as members of embodiment 1, and that are mentioned in that embodiment are indicated by the same reference numerals and description thereof is omitted.

The present embodiment will describe a chip-stack semiconductor device which includes multiple in general and five in particular semiconductor chips of embodiment 1 stacked on top of each other.

Referring to FIG. 10, a chip-stack semiconductor device 40 of the above arrangement includes five semiconductor chips 1 being stacked (in the order of a first semiconductor chip 1a, second semiconductor chip 1b, third semiconductor chip 1c, fourth semiconductor chip 1d, and a fifth semiconductor chip 1e from the bottom).

The figure shows that in the chip-stack semiconductor device 40, the leftmost, the second left, and the fifth left through electrodes 8 are used as signal-routing through electrodes 8c. A single through electrode 8 electrically connects all the way from the uppermost, fifth semiconductor chip 1e down to the lowermost, first semiconductor chip 1a, including those intervening three semiconductor chips 1b, 1c, 1d.

Meanwhile, in the figure, the third left and the fourth left through electrodes 8 are used as, for example, grounding through electrodes 8b. Two through electrodes 8 electrically connects all the way from the uppermost, fifth semiconductor chip 1e down to the lowermost, first semiconductor chip 1a, including those intervening three semiconductor chips 1b, 1c, 1d.

That is, on the uppermost, fifth semiconductor chip 1e, the third left and the fourth left through electrodes 8 are electrically connected via a conductive film 20 and a bump 25 in the figure.

The through electrodes 8 for the semiconductor chips 1a-10e are contact through electrodes 18 electrically connected to the device regions of the semiconductor chips 1a-10e, and connected to respective electrode pads 7.

As discussed in the foregoing, when the positions of the electrode terminals for all the semiconductor chips 1 match, this configuration can be employed.

However, the positions of the electrode terminals for vertically adjacent semiconductor chips 1 often do not match on a pattern lay-out.

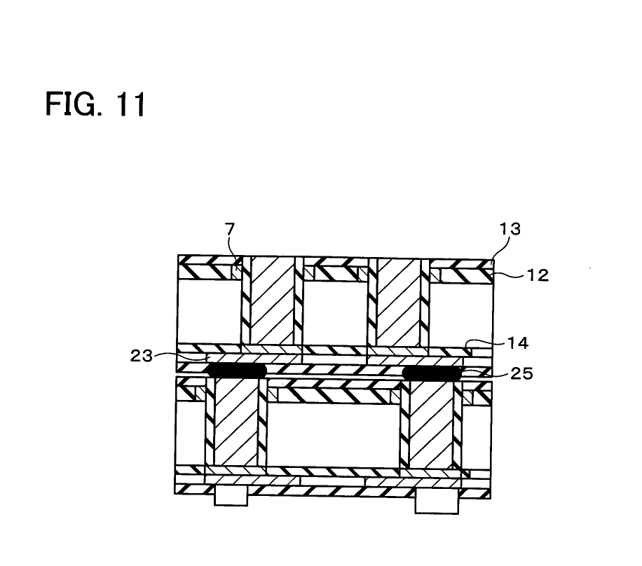

In the present embodiment, the problem is addressed, as shown in FIG. 11, by re-wiring 23 the back of the wafer.

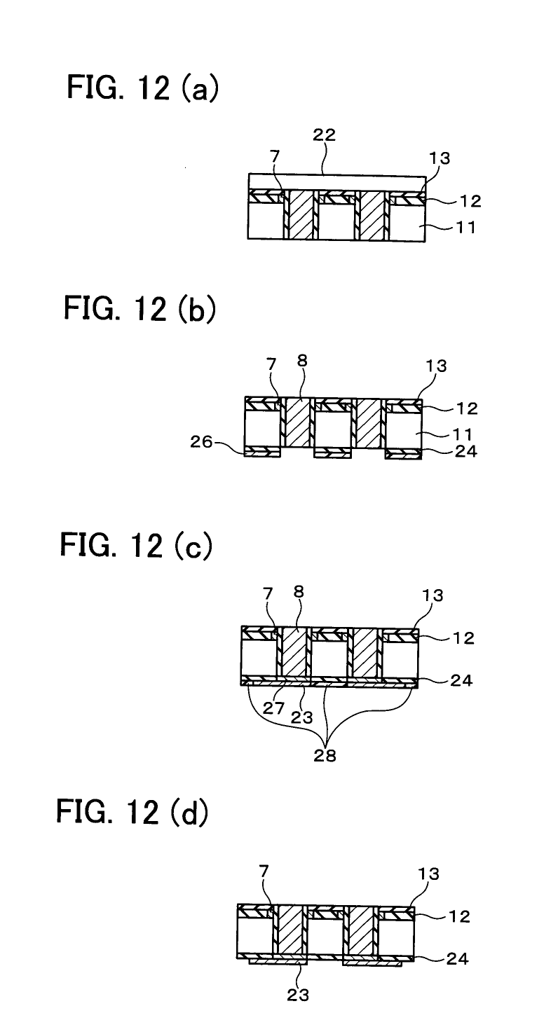

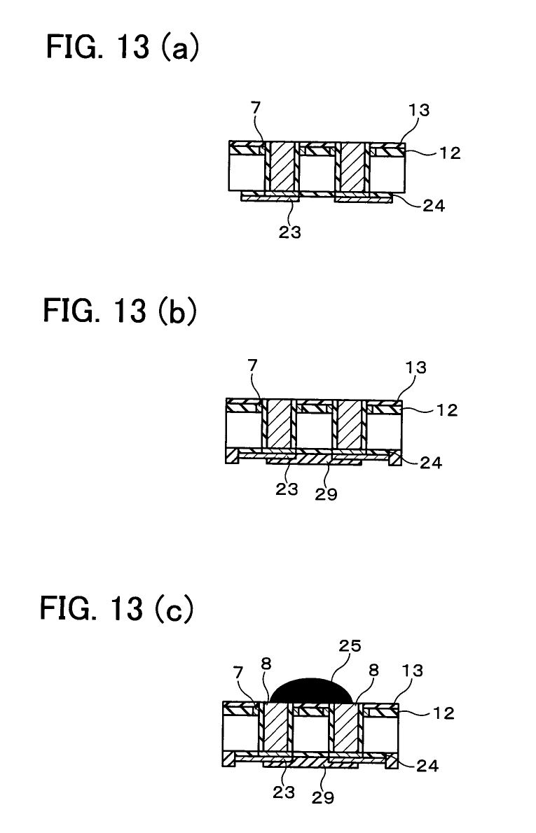

The formation of the re-wiring 23 will be described with reference to FIG. 12 and FIG. 13: first, after completely polishing the back of the wafer, before the support board 22 is removed as shown in FIG. 12(a), an insulating film 24 is vapor-deposited on the back of the semiconductor wafer 11 as shown in FIG. 12(b); after a resist 26 is applied, the insulating film 24 is etched where through electrodes 8 will be formed, using a reduction projection aligner.

Subsequently, as shown in FIG. 12(c), a barrier metal 27 is sputtered, another resist 28 is applied; thereafter, a conductive material will be electroplated for the rewiring 23. After the electroplating ends, the resist 28 is peeled as shown in FIG. 12(d), the plating is removed, as shown in FIG. 13(a), by a chemical where it is not necessary, and a protection film 29 is attached thereon as shown in FIG. 13(b), and openings are made by etched. Thereafter, the support board 22 is peeled. In FIGS. 12(b)-12(d), 13(a), and 13(b), the support board 22 is omitted.

In the present embodiment, this finishes the process, and the product is ready for connection to the bottom chip 10 via the bumps 25 as shown in FIG. 11 mentioned earlier.

Alternatively, for example, as shown in FIG. 13(c), the top of two through electrodes 8 can be connected via bumps 25.

As discussed in the foregoing, in the chip-stack semiconductor device 40 of the present embodiment, where extended interconnects are required, the number of through electrodes 8 is increased in accordance with the length to increase the relative cross-sectional area. This reduces the resistance of the electrode and alleviates voltage drop, heat, delay, and loss. Variations in resistance between terminals can also be reduced.

In the example above, the contact through electrodes 18 are all used. Alternatively, some of the through electrodes 8 may not be connected to the semiconductor chip 1, more specifically, the electrode pads 7, i.e., not electrically connected to the device region (non-contact through electrodes 19). This allows a current to flow all the way from the top chip 10 to the bottom chip 10.

### Embodiment 3

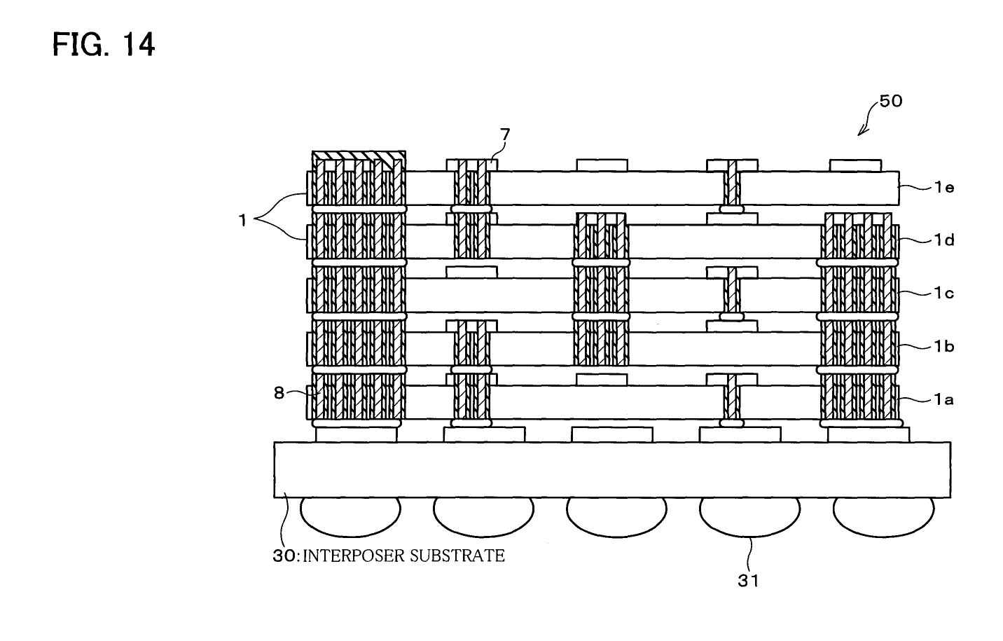

The following will describe another embodiment of the present invention with reference to FIG. 14. For convenience, members of the present embodiment that have the same arrangement and function as members of embodiments 1, 2, and that are mentioned in that embodiment are indicated by the same reference numerals and description thereof is omitted.

The present embodiment will describe a chip-stack semiconductor device 50 in which the number of through electrodes 8 is increased according to the length of interconnecting lines which increases because of stacking of multiple semiconductor chips 1.

Referring to FIG. 14, the chip-stack semiconductor device 50 includes an interposer substrate 30 on which are five sequentially stacked semiconductor chips 1: a first semiconductor chip 1a, a second semiconductor chip 1b, a third semiconductor chip 1c, a fourth semiconductor chip 1d, and a fifth semiconductor chip 1e.

The figure shows that interconnect lines are longer from the uppermost, fifth semiconductor chip 1e down to the external lead electrodes 31 on the interposer substrate 30 than from the lowermost, first semiconductor chip 1a down to the external lead electrodes 31 on the interposer substrate 30.

More specifically, for example, when connecting the electrode pads 7 on the fifth semiconductor chip 1e to the external lead electrodes 31 on the interposer substrate 30 or when connecting the fifth semiconductor chip 1e to the through electrodes 8 on the first semiconductor chip 1a, lines become extended, and their resistance increased, causing signal delay, heat, and other problems. Therefore, in these cases, the line resistance is preferably reduced to a minimum value and varies from line to line as little as possible.

Accordingly, in the present embodiment, to eliminate variations of resistance between those through electrodes 8 which connect adjacent semiconductor chips 1 and those which extend through at least one semiconductor chip 1 for connection, the cross-sectional areas of the through electrodes 8 are adjusted through increases of the number of the through electrodes 8. More specifically, the number of through electrodes 8 is determined according to the length of interconnecting lines through the multiple stacked semiconductor chips 1.

To generalize the concept, more through electrodes 8 are used for connections between n+1 or more adjacent semiconductor chips 1 (n is an integer more than or equal to 2) than for connections between n adjacent semiconductor chips 1 (n is an integer more than or equal to 2).

Specifically, in the present embodiment, to stack semiconductor chips 1 of the same thickness, a single through electrode 8 is used to connect one semiconductor chip 1 to the interposer substrate 30; two through electrodes 8 are used to connect two adjacent semiconductor chips 1 to the interposer substrate 30; three through electrodes 8 are used to connect three adjacent semiconductor chips 1 to the interposer substrate 30; four through electrodes 8 are used to connect four adjacent semiconductor chips 1 to the interposer substrate 30; and five through electrodes 8 are used to connect five adjacent semiconductor chips 1 to the interposer substrate 30.

Therefore, in the present embodiment, the number of through electrodes 8 increases in proportion to the interconnect line length through the multiple stacked semiconductor chips 1. This makes uniform the line resistance of the through electrodes 8.

The same approach where the number of through electrodes 8, thus the cross-sectional area, is increased in proportion to line length is also applicable to semiconductor chips 1 with various thicknesses being stacked. The approach alleviates variation in resistance from terminal to terminal, and reduces resistance of extended lines.

Further, for the power supply terminal, the ground terminal, etc. of the semiconductor chip 1, a few through electrodes 8 are used to increase the cross-sectional area, which alleviates heating, signal delay, etc.

As discussed in the foregoing, in the chip-stack semiconductor device 50 of the present embodiment, more through electrodes 8 are used for connections between n+1 or more adjacent semiconductor chips 1 (n is an integer more than or equal to 2) than for connections between n adjacent semiconductor chips 1 (n is an integer more than or equal to 2).

Therefore, the number of through electrodes 8 increases in accordance with the number of semiconductor chips 1 vertically stacked in the chip-stack semiconductor device 50. Hence, the relative cross-sectional area of the through electrodes 8 can be increased in accordance with the interconnect line length. This reduces the resistance value of the electrodes, and alleviates voltage drop, heating, delay, and loss.

In the chip-stack semiconductor device 50 of the present embodiment, the through electrodes 8 are formed with a relatively large cross-sectional area according to the interconnect line length through the multiple stacked semiconductor chips 1. Thus, the chip-stack semiconductor device 50 can be provided which is capable of preventing the electrodes's resistance from developing excessive voltage drop, heat, delay, and loss, and also from varying from one electrode to the other.

In the chip-stack semiconductor device 50 of the present embodiment, more through electrodes 8 are used in proportion to the interconnect line length through the multiple stacked semiconductor chips 1. The number of through electrodes 8, thus the cross-sectional area, can be readily determined.

As in the foregoing, a semiconductor device in accordance with the present invention is such that at least one type of the through electrodes is contact through electrodes electrically connected to the semiconductor chip.

According to the invention, as to the contact through electrodes electrically connected to the semiconductor chip 1, relatively increasing the number, hence the combined cross-sectional area, of the through electrodes for the terminals required to conduct large electric current helps efficient operation of the semiconductor chip.

Another semiconductor device in accordance with the present invention is such that in the foregoing semiconductor device, at least one type of the through electrodes is non-contact through electrodes not electrically connected to the semiconductor chip.

According to the invention, as the through electrodes, non-contact through electrodes are provided which are not electrically connected to the semiconductor chip.

Therefore, the heat generated in the semiconductor device can be discharged outside via the non-contact through electrodes.

Another semiconductor device in accordance with the present invention is such that in the foregoing semiconductor device, the number of those through electrodes which are connected to a ground terminal or a power supply terminal of the semiconductor chip are greater than the number of those through electrodes which are connected to a signal terminal.

More specifically, in the semiconductor chip, the ground terminal or the power supply terminal conduct greater electric current than the signal terminal.

As to this point, in the present invention, the number of the through electrodes connected to either the ground terminal or the power supply terminal of the semiconductor chip is greater than the number of the through electrodes connected to its signal terminal.

Therefore, increasing the number, hence the combined cross-sectional area, of the through electrodes for the ground terminal or the power supply terminal of the semiconductor chip required to conduct large electric current reduces the resistance of the through electrodes and alleviates heating, signal delay, etc. Variations in resistance between terminals can also be reduced.

A chip-stack semiconductor device in accordance with the present invention is such that in the foregoing chip-stack semiconductor device, the number of those through electrodes which connect n+1 or more adjacent semiconductor chips are greater than the number of those through electrodes which connect n adjacent semiconductor chips, where n is an integer more than or equal to 2.

According to the invention, the number of the through electrodes increases in accordance with the number of vertically stacked semiconductor chips to be connected. Hence, the relative cross-sectional areas of the through electrodes required to make interconnects over an extended length can be increased in accordance with that length.

Hence, the combined cross-sectional area of the through electrodes can be increased in accordance with that length. This reduces the resistance of the electrodes and alleviates voltage drop, heat, delay, and loss.

Another chip-stack semiconductor device in accordance with the present invention is such that in the foregoing chip-stack semiconductor device, the number of the through electrodes is increased according to an interconnect line length through the multiple stacked semiconductor chips.

According to the invention, the through electrodes have a combined cross-sectional area which is increased according to the interconnect line length through the multiple stacked semiconductor chips. Thus, a chip-stack semiconductor device can be offered which is capable of preventing the electrodes' resistance from developing excessive voltage drop, heat, delay, and loss, and also from varying from one electrode to the other.

Another chip-stack semiconductor device in accordance with the present invention is such that in the foregoing chip-stack semiconductor device, the number of is increased in proportion to an interconnect line length through the multiple stacked semiconductor chips.

According to the invention, the number, hence the cross-sectional area, of the through electrodes can be readily determined.

The invention being thus described, it will be obvious that the same way may be varied in many ways. Such variations are not to be regarded as a departure from the spirit and scope of the invention, and all such modifications as would be obvious to one skilled in the art are intended to be included within the scope of the following claims.

What is claimed is:

1. A semiconductor device, comprising a number of through electrodes with equal cross-sectional areas in a semiconductor chip linking a front surface to a back surface thereof, the number of the through electrodes being determined according to a magnitude of an electric current with respect to an identical signal.

2. The semiconductor device as set forth in claim 1, wherein at least one type of the through electrodes is contact through electrodes electrically connected to that semiconductor chip.

3. The semiconductor device as set forth in claim 1, wherein at least one type of the through electrodes is non-contact through electrodes not electrically connected to that semiconductor chip.

4. The semiconductor device as set forth in claim 1, wherein a number of those through electrodes which are connected to a ground terminal or a power supply terminal of the semiconductor chip is greater than a number of those through electrodes which are connected to a signal terminal thereof.

5. A chip-stack semiconductor device, comprising multiple stacked semiconductor chips, each of the semiconductor chips including a number of through electrodes with equal cross-sectional areas therein linking a front surface to a back surface thereof, the number of the through electrodes being determined according to a magnitude of an electric current with respect to an identical signal.

6. A chip-stack semiconductor device, comprising multiple stacked semiconductor chips, each of the semiconductor chips including a number of through electrodes with equal cross-sectional areas therein linking a front surface to a back surface thereof, the number of the through electrodes being determined according to a magnitude of an electric current with respect to an identical signal,
wherein
at least one type of the through electrodes is contact through electrodes electrically connected to that semiconductor chip.

7. A chip-stack semiconductor device, comprising multiple stacked semiconductor chips, each of the semiconductor chips including a number of through electrodes with equal cross-sectional areas therein linking a front surface to a back surface thereof, the number of the through electrodes being determined according to a magnitude of an electric current with respect to an identical signal,
wherein
at least one type of the through electrodes is non-contact through electrodes not electrically connected to that semiconductor chip.

8. A chip-stack semiconductor device, comprising multiple stacked semiconductor chips, each of the semiconductor chips including a number of through electrodes with equal cross-sectional areas therein linking a front surface to a back surface thereof, the number of the through electrodes being determined according to a magnitude of an electric current with respect to an identical signal,
wherein
a number of those through electrodes which are connected to a ground terminal or a power supply terminal of that semiconductor chip is greater than a number of those through electrodes which are connected to a signal terminal thereof.

9. The chip-stack semiconductor device as set forth in claim 5, wherein a number of those through electrodes which connect n+1 or more adjacent semiconductor chips is greater than a number of those through electrodes which connect n adjacent semiconductor chips, where n is an integer more than or equal to 2.

10. The chip-stack semiconductor device as set forth in claim 6, wherein a number of those through electrodes which connect n+1 or more adjacent semiconductor chips is greater than a number of those through electrodes which connect n adjacent semiconductor chips, where n is an integer more than or equal to 2.

11. The chip-stack semiconductor device as set forth in claim 7, wherein a number of those through electrodes which connect n+1 or more adjacent semiconductor chips is greater than a number of those through electrodes which connect n adjacent semiconductor chips, where n is an integer more than or equal to 2.

12. The chip-stack semiconductor device as set forth in claim 8, wherein a number of those through electrodes which connect n+1 or more adjacent semiconductor chips is greater than a number of those through electrodes which connect n adjacent semiconductor chips, where n is an integer more than or equal to 2.

13. The chip-stack semiconductor device as set forth in claim 5, wherein the number of the through electrodes is increased according to an interconnect line length through the multiple stacked semiconductor chips.

14. The chip-stack semiconductor device as set forth in claim 6, wherein the number of the through electrodes is increased according to an interconnect line length through the multiple stacked semiconductor chips.

15. The chip-stack semiconductor device as set forth in claim 7, wherein the number of the through electrodes is increased according to an interconnect line length through the multiple stacked semiconductor chips.

16. The chip-stack semiconductor device as set forth in claim 8, wherein the number of the through electrodes is increased according to an interconnect line length through the multiple stacked semiconductor chips.

17. The chip-stack semiconductor device as set forth in claim 13, wherein the number of the through electrodes is increased in proportion to an interconnect line length through the multiple stacked semiconductor chips.

18. The chip-stack semiconductor device as set forth in claim 14, wherein the number of the through electrodes is increased in proportion to an interconnect line length through the multiple stacked semiconductor chips.

19. The chip-stack semiconductor device as set forth in claim 15, wherein the number of the through electrodes is increased in proportion to an interconnect line length through the multiple stacked semiconductor chips.

20. The chip-stack semiconductor device as set forth in claim 16, wherein the number of the through electrodes is increased in proportion to an interconnect line length through the multiple stacked semiconductor chips.
